(19) United States
(12) Patent Application Publication
(10) Pub. No.: US 2014/0328127 A1
(43) Pub. Date: Nov. 6, 2014

(54) Method of Managing Non-Volatile Memory and Non-Volatile Storage Device Using the Same

(71) Applicant: Skymedi Corporation, Hsinchu City (TW)

(72) Inventors: Ming-Yu Tai, Hsinchu City (TW); Yi-Chun Liu, Hsinchu City (TW)

(73) Assignee: Skymedi Corporation, Hsinchu City (TW)

(21) Appl. No.: 13/953,764

(22) Filed: Jul. 30, 2013

Related U.S. Application Data
(60) Provisional application No. 61/818,884, filed on May 2, 2013.

(51) Int. Cl. G11C 16/10

(52) U.S. Cl. CPC G11C 16/10
USPC 365/185.12

(57) ABSTRACT

A method of managing a non-volatile memory where the non-volatile memory comprises a plurality of memory blocks and each of the plurality of memory blocks includes a plurality of memory pages includes partitioning a memory page among the plurality of memory pages into a plurality of clusters; and writing data and a mapping information corresponding to the data into different clusters of the plurality of clusters.

### CROSS REFERENCE TO RELATED APPLICATIONS

This application claims the benefit of U.S. Provisional Application No. 61/818,884, filed on May 2, 2013 and entitled “Address transfer & data management for a non-volatile memory”, the contents of which are incorporated herein by reference.

### BACKGROUND OF THE INVENTION

1. Field of the Invention

The present invention relates to a method of managing a non-volatile memory and a non-volatile storage device using the same, and more particularly, to a method of managing a non-volatile memory which is capable of writing data and mapping information into a memory page by a programming operation on the memory page and a non-volatile storage device using the same.

2. Description of the Prior Art

In a typical non-volatile storage device, the host usually manages the non-volatile memory based on a unit of sector, and the minimum programming unit of the non-volatile memory is usually determined based on a unit of a memory page. Traditionally, the size of a sector is defined to be equal to the size of a memory page, so that the programming efficiency can be maximized when page mapping is utilized. When the host needs to write a sector of data into the non-volatile memory, the data can be written into an entire memory page using page mapping, and no space in the memory page is wasted.

In recent years, with higher requirements for large storage space, the size of non-volatile memory is increased continuously, and the size of memory page is correspondingly increased. However, the sector size remains without notable change. In such a condition, when a sector of data within a memory page needs to be updated, this sector of updated data should be written into a new memory page and there will be redundant memory space in the new memory page required to be filled with other data in the original memory page, which causes a waste of memory space and reduction of programming efficiency. For example, please refer to FIG. 1, which is a schematic diagram of data D1 written into a memory page P1. If the size of the data D1 is equal to 4 kB and the size of the memory page P1 is equal to 16 kB, when the host needs to write the data D1 into the memory page P1 by a memory controller, the data D1 may occupy 4 kB space in the memory page P1 and there will be 12 kB memory space required to store other data. Therefore, such 12 kB memory space may be wasted, and the program operation will occupy 12 kB bandwidth of the memory controller since the memory controller has to program the entire memory page (16 kB) at a time but there is only 4 kB data needs to be written. In such a condition, the programming efficiency is reduced significantly.

In a typical non-volatile memory, data is written into a memory page in a programming operation, and such data may be a user data, mapping information of user data, garbage collection data, or wear-leveling data, etc. Different types of data among these data may be programmed into different memory pages. For example, when a sector of user data needs to be written into the non-volatile memory, the mapping information corresponding to the data should be updated accordingly; hence at lease 2 memory pages are assigned to process the user data (1 page for user data and 1 page for mapping information). In such a condition, the memory page used to store the user data may be wasted and the writing operation may need further programming operation for updating the mapping information. Therefore, the programming capability of the memory controller may not be utilized efficiently. Thus, there is a need for improvement over the prior art.

### SUMMARY OF THE INVENTION

It is therefore an objective of the present invention to provide a method of managing a non-volatile memory which is capable of writing data and mapping information into a memory page by a programming operation.

The present invention discloses a method of managing a non-volatile memory. The non-volatile memory comprises a plurality of memory blocks, and each of the plurality of memory blocks comprises a plurality of memory pages. The method comprises partitioning a memory page among the plurality of memory pages into a plurality of clusters; and writing data and a mapping information corresponding to the data into different clusters of the plurality of clusters.

The present invention further discloses a non-volatile storage device, which comprises a non-volatile memory and a memory controller. The non-volatile memory comprises a plurality of memory blocks, each comprising a plurality of memory pages. The memory controller, coupled to the non-volatile memory, is utilized for managing the non-volatile memory by executing the following steps: partitioning a memory page among the plurality of memory pages into a plurality of clusters; and writing data and a mapping information corresponding to the data into different clusters of the plurality of clusters.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of data written into a memory page.

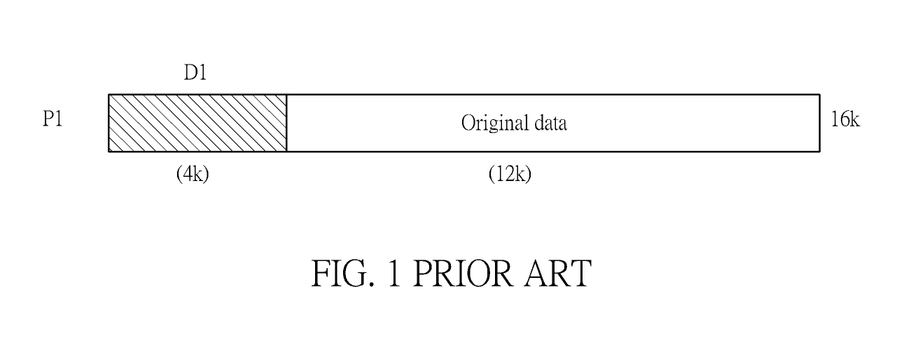

FIG. 2 is a schematic diagram of a non-volatile storage device controlled by a host according to an embodiment of the present invention.

FIG. 3 is a schematic diagram of a memory page according to an embodiment of the present invention.

FIG. 4 is a schematic diagram of memory pages according to an embodiment of the present invention.

FIG. 5 is a schematic diagram of super pages according to an embodiment of the present invention.

FIG. 6 is a schematic diagram of a super page performing backup according to an embodiment of the present invention.

FIG. 7 is a schematic diagram of super pages according to an embodiment of the present invention.

### DETAILED DESCRIPTION

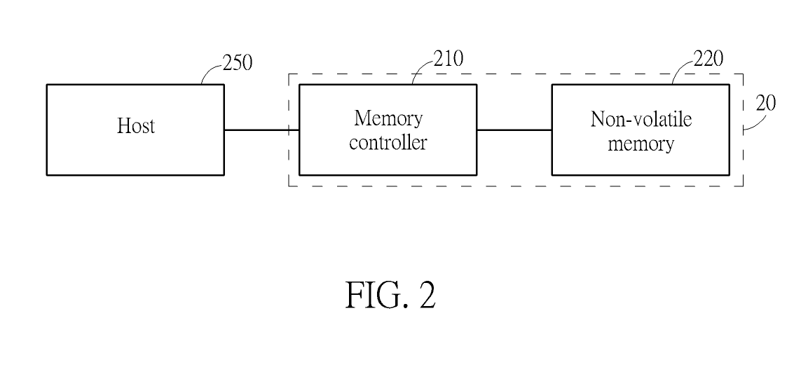

Please refer to FIG. 2, which is a schematic diagram of a non-volatile storage device 20 controlled by a host 250 according to an embodiment of the present invention. As shown in FIG. 2, the non-volatile storage device 20 includes a memory controller 210 and a non-volatile memory 220. The non-volatile memory 220 is composed of a plurality of memory blocks, and each memory block among the plurality of memory blocks is composed of a plurality of memory pages. The non-volatile memory 220 may be a NAND flash memory or other types of non-volatile memories. The memory controller 210 is utilized for managing the non-volatile memory 220. The memory controller 210 communicates with the host 250 so that the host can read data from the non-volatile memory 220 and write data into the non-volatile memory 220 via the memory controller 210. In a process of data programming, the host 250 manages the data in logical storage space, and the memory controller 210 is responsible for managing the data through a mapping between the logical storage space and a physical storage space of the non-volatile memory 220.

In the prior art, when a sector of data (4 kB) needs to be written into a memory page (16 kB), the bandwidth of the controller 210 will be wasted, and the redundant memory space in the non-volatile memory 220 should be utilized for storing other data. On the other hand, when the size of a memory page is equal to the size of a sector, the efficiency can be maximized. Therefore, it is desirable to partition a memory page into a plurality of clusters according to the sector size, so that a sector of data can be stored in a cluster. In such a condition, the physical address of the memory page can be mapping to the logical address with a unit of cluster. For example, if the size of a memory page is equal to 16 kB and the size of a sector is equal to 4 kB, the memory page is preferably partitioned into 4 clusters, so that each sector of data can be stored in an entire cluster. In the memory page, a physical cluster is mapping to a logical cluster. As a result, each cluster can be utilized for storing a sector of data, and no memory space is wasted.

In order to efficiently utilize the memory space and the bandwidth of the memory controller 210, the clusters in each memory page should be fully occupied by useful data. In some embodiments, in each programming operation the length of user data required to be written may not be equal to 4 sectors. If there are only 2 sectors of user data required to be stored, only 2 clusters in the memory page are occupied by desired user data. In such a condition, the other 2 clusters can be utilized for storing other data such as mapping information, garbage collection data or wear-leveling data. Therefore, the data written into a memory page may include different types of data such as a user data, mapping information, garbage collection data, and wear-leveling data. As a result, different types of data may be written into a memory page in a programming operation.

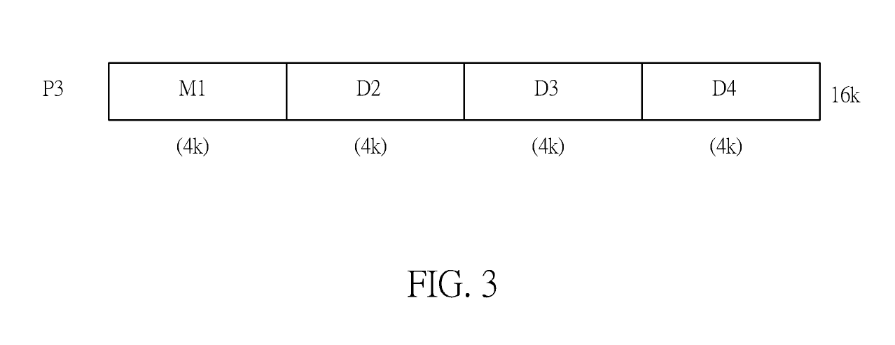

For example, please refer to FIG. 3, which is a schematic diagram of a memory page P3 according to an embodiment of the present invention. As shown in FIG. 3, there are 3 sectors of user data D2-D4 required to be written into the memory page P3. Since the size of the memory page P3 is equal to 16 kB and the length of a sector is equal to 4 kB, the memory page P3 can be partitioned into 4 clusters. Within the memory page P3, 3 clusters is utilized for storing the user data D2-D4 and the other cluster may be utilized for storing mapping information M1. In other words, the user data D2-D4 and the mapping information M1 are written into different clusters of the memory page P3 in a programming operation.

In general, the mapping information M1 records the information related to the logical addresses of the user data D2-D4 mapping to the physical addresses of the corresponding clusters in the memory page P3. The mapping information M1 may also include information related to mapping from a physical address to a logical address. In some embodiments, the mapping information M1 includes the information related to mapping from the physical address of the memory page P3 to the logical addresses of the user data D2-D4. In some embodiments, the controller may use those mapping information, logical address mapping to physical address and physical address mapping to logical address, to operate garbage collection and/or wear-leveling.

Please note that, when the mapping information stored in a specific memory page includes information related to mapping of the data stored in other clusters of the specific memory page, the data and the corresponding mapping information can be updated in a programming operation. In such a condition, power-off recovery (POR) management may be performed more easily. In a conventional non-volatile memory, data and corresponding mapping information should be written into the non-volatile memory separately. Once an accidental power off occurs, the memory controller should perform POR according to whether the data has been updated and whether the corresponding mapping information has been updated. In comparison, in the non-volatile memory of the above embodiment of the present invention, data and corresponding mapping information can be written into different clusters by a programming operation. In such a condition, when an accidental power off occurs and POR needs to be performed, the question can be simplified to whether the data and corresponding mapping information have been updated; that is, the data and corresponding mapping information are inevitably updated at the same time, which significantly reduces complexity of performing POR.

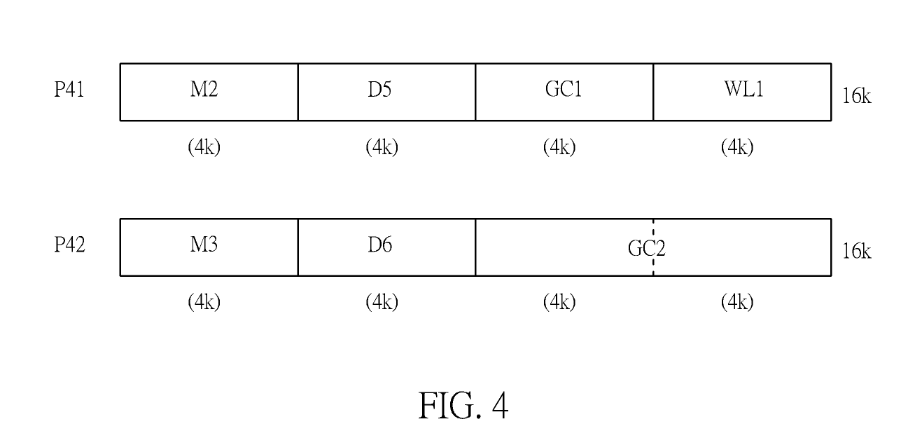

In some embodiments, there may be only one sector of user data required to be stored in the non-volatile memory, and mapping information is updated correspondingly. Please refer to FIG. 4, which is a schematic diagram of memory pages P41 and P42 according to an embodiment of the present invention. As shown in FIG. 4, a sector of user data D5 and corresponding mapping information M2 need to be written into the memory page P41. Since the size of the memory page P41 is equal to 16 kB and the length of a sector is equal to 4 kB, the memory page P41 can be partitioned into 4 clusters. However, there are only one user data D5 and the corresponding mapping information M2 written into the memory page P41, and these data may only occupy 2 clusters of the memory page P41 and the other 2 clusters may become unnecessary. In order to utilize the memory page P41 efficiently, these 2 clusters can be utilized for storing garbage collection data or wear-leveling data. As shown in FIG. 4, a sector of garbage collection data GC1 and a sector of wear-leveling data WL1 are written into the memory page P41 together with the user data D5, and mapping information corresponding to the garbage collection data GC1 and the wear-leveling data WL1 may also be included in the mapping information M2.

Please note that the data to be filled into clusters may have a size greater than a cluster size; hence more than one cluster are required for storing the data, as shown by the memory page P42 in FIG. 4. A sector of user data D6 and corresponding mapping information M3 are written into the memory page P42. The size of the memory page P42 is also equal to 16 kB and can be partitioned into 4 clusters. In the memory page P42, 2 clusters are occupied by the user data D6 and the mapping information M3, respectively, and the other 2 clusters may both be utilized for storing garbage collection data GC2. If the size of the garbage collection data GC2 is greater than 4 kB (e.g. equal to 8 kB), the garbage collection data GC2 may be filled into these 2 clusters in the memory page P42, so that the space of the memory page P41 can be utilized efficiently, and the efficiency of the memory controller may also be optimized.

For a typical non-volatile memory, the process of garbage collection involves moving valid data from a memory page to another memory page before erasing the memory block. The process of wear-leveling involves arranging data so that erasures and writes of data are distributed evenly across the non-volatile memory, in order to prolong the life of the non-volatile memory. In the conventional non-volatile memory, the data processed by the operation of garbage collection and wear-leveling may be performed individually. In comparison, in the above embodiment of the present invention, since a memory page is partitioned into clusters and each physical cluster is mapping to the logical cluster, garbage collection data and wear-leveling data can be written into different clusters of a memory page. As shown in the memory page P41 of FIG. 4, after 2 clusters are filled with the user data D5 and the mapping information M2 respectively, the other 2 clusters can be utilized for storing the garbage collection data GC1 and the wear-leveling data WL1, which indicates the memory controller to perform garbage collection and wear-leveling that originally need to be performed at a later time. As a result, the efficiency of performing garbage collection and wear-leveling can be enhanced.

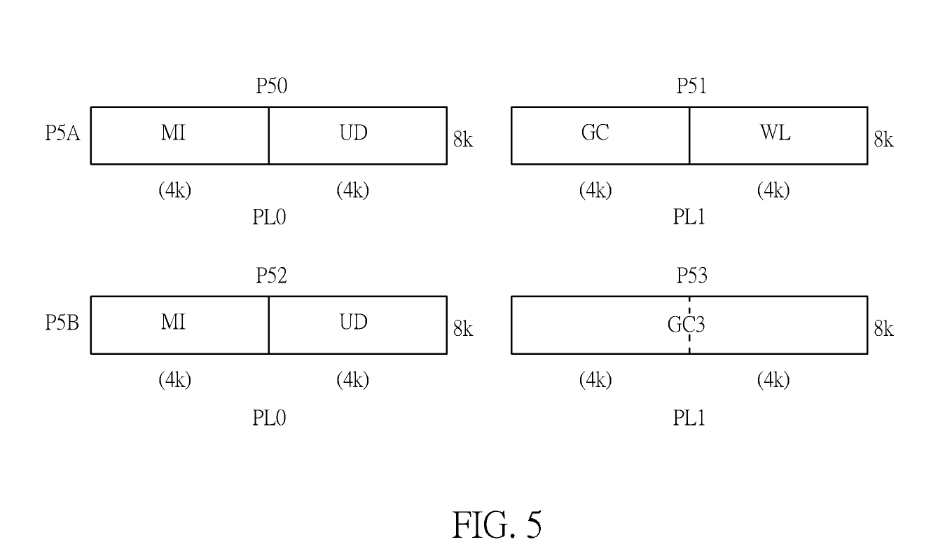

Please note that the above embodiments may also be applied to multi-plane programming. In some embodiments, several memory pages in different memory blocks of different planes can be combined into a super page. Please refer to FIG. 5, which is a schematic diagram of super pages P5A and P5B according to an embodiment of the present invention. As shown in FIG. 5, the super page P5A is composed of memory pages P50 and P51, wherein the memory page P50 is located on a plane PL0 and the memory page P51 is located on a plane PL1. The size of each memory page is equal to 8 kB, and the unit of sector that the host manages the non-volatile memory is 4 kB; hence each of the memory pages P50 and P51 may be partitioned into 2 clusters. In a programming operation, data is written into both memory pages P50 and P51 within the super page P5, and 4 sectors of data can be written into the entire super page, wherein the data may be mapping information (MI), user data (UD), garbage collection data (GC) or wear-leveling data (WL), as illustrated by the super page P5A.

Similarly, when the size of data is greater than a cluster size, more than one cluster is required for storing the data, as shown by the super page P5B. The super page P5B is composed of memory pages P52 and P53, wherein the memory page P52 is located on the plane PL0 and the memory page P53 is located on the plane PL1. The size of each memory page is equal to 8 kB, and the unit of sector that the host manages the non-volatile memory is 4 kB; hence each of the memory pages P52 and P53 may be partitioned into 2 clusters. Mapping information and user data are stored in a cluster of the memory page P52, respectively. Garbage collection data GC3 has a size equal to 8 kB, and should occupy 2 clusters in the super page P5B. As shown in FIG. 5, both clusters of the memory page P53 are filled with the garbage collection data GC3.

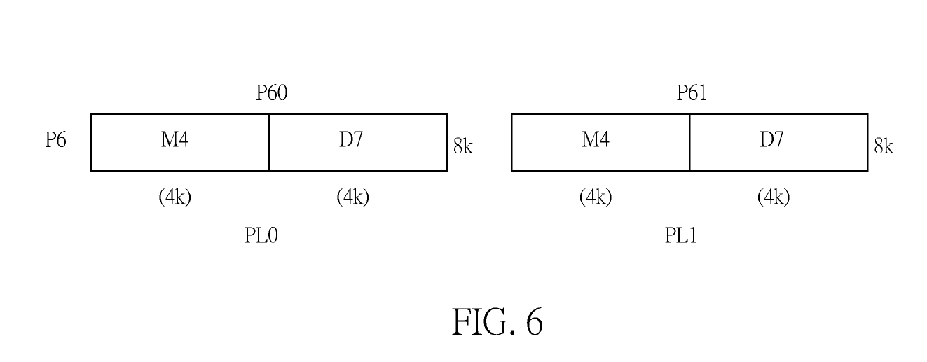

In some embodiments with the super page, backup can be performed indifferent memory pages within the super page. Please refer to FIG. 6, which is a schematic diagram of a super page P6 performing backup according to an embodiment of the present invention. As shown in FIG. 6, the super page P6 is composed of memory pages P60 and P61, wherein the memory page P60 is located on the plane PL0 and the memory page P61 is located on the plane PL1. The size of each memory page is equal to 8 kB, and the unit of sector that the host manages the non-volatile memory is 4 kB; hence each of the memory pages P60 and P61 may be partitioned into 2 clusters. When user data D7 need to be written into the super page P6, the user data D7 may be written into both the memory pages P60 and P61 to perform backup. Mapping information M4 corresponding to the user data D7 may also be updated in both of the memory pages P60 and P61. In such a condition, all clusters in the super page P6 are utilized efficiently, and no redundant memory pages are wasted. The bandwidth of the memory controller will not be wasted as well.

In the conventional non-volatile storage system, when user data needs to be written into the non-volatile memory, the backup scheme is usually performed by reserving the user data in a buffer of the host until the programming is completed successfully. In such a condition, the buffer is occupied during the entire programming time. In comparison, if the user data is written into 2 memory pages in a programming operation, one of the memory pages can be considered as a backup. In such a condition, the buffer of the host can be released after the host commands the memory controller to program, which significantly reduces the requirement of buffer space usage.

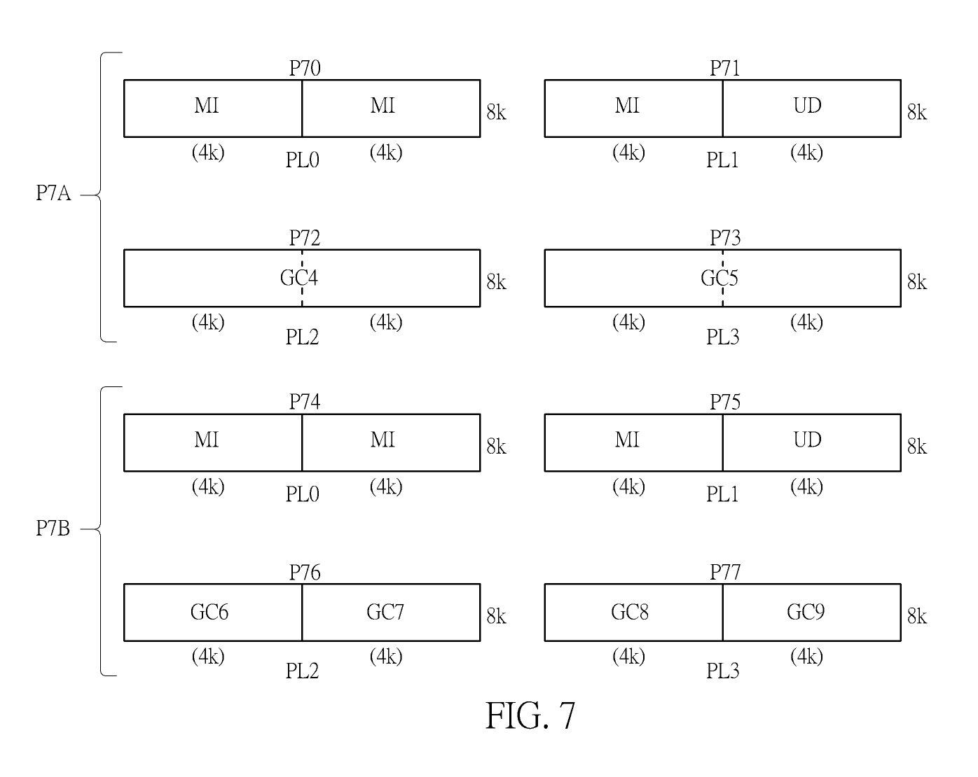

Please refer to FIG. 7, which is a schematic diagram of super pages P7A and P7B according to an embodiment of the present invention. As shown in FIG. 7, the super pages P71 and P72 have a 4-plane structure. The super page P7A includes 4 memory pages P70-P73 located on the planes PL0-PL3 respectively, and the super page P7B includes 4 memory pages P74-P77 located on the planes PL0-PL3 respectively. The size of each memory page is equal to 8 kB, and the unit of sector that the host manages the non-volatile memory is 4 kB; hence each of the memory pages P70-P77 may be partitioned into 2 clusters with each cluster equal to 4 kB. Even if only one user data needs to be stored in the super page P7A or P7B so that only one cluster in the super page P7A or P7B is occupied by the user data, other clusters may be filled with garbage collection data and corresponding mapping information. For the super page P7A, garbage collection data GC4 has a size equal to 8 kB and occupies both clusters of the memory page P72; garbage collection data GC5 has a size equal to 8 kB and occupies both clusters of the memory page P73. Since the mapping information corresponds to the user data and the garbage collection data GC4 and GC5, the mapping information may also require more than one cluster. In such a condition, both clusters of the memory page P70 and one cluster of the memory page P71 are utilized for storing the mapping information. For the super page P7B, the size of each of garbage collection data GC6-GC9 is equal to 4 kB and each of the garbage collection data GC6-GC9 is filled into a cluster within the memory page P76 or P77. Since the mapping information corresponds to the user data and the garbage collection data GC6-GC9, the mapping information may also require more than one cluster. In such a condition, both clusters of the memory page P74 and one cluster of the memory page P75 are utilized for storing the mapping information.

Please note that, the present invention is capable of partitioning a memory page into clusters according to the size of sector that the host manages the non-volatile memory, and writing different types of data into different clusters. Those skilled in the art can make modifications and alternations accordingly. For example, in a programming operation, the written data can be any types of data according to system requirements, which may be but not limited to user data, garbage collection data, wear-leveling data or mapping information corresponding to each kind of data. In addition, the placement of these data in different clusters may also be determined according to system requirements, e.g. POR or backup requirements.

In the prior art, when a sector of data within a memory page needs to be updated, this sector of updated data should be written into a new memory page and there will be redundant memory space in the new memory page required to be filled with other data in the original memory page, which causes a waste of memory space and reduction of programming efficiency. Besides, only one type of data can be written into a memory page in each programming operation. In comparison, the memory page can be partitioned into a plurality of clusters and each logical cluster is mapping to a physical cluster. Different types of data can be stored in different clusters in the same memory page, which enhances efficiency of bandwidth usage of the memory controller and the memory space usage. In addition, the performance of user data backup and POR management may also be enhanced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of managing a non-volatile memory, the non-volatile memory comprising a plurality of memory blocks, each of the plurality of memory blocks comprising a plurality of memory pages, the method comprising:
partitioning a memory page among the plurality of memory pages into a plurality of clusters; and
writing data and a mapping information corresponding to the data into different clusters of the plurality of clusters.

2. The method of claim 1, further comprising:
mapping a logic address to a physical address with a unit of a cluster.

3. The method of claim 1, wherein the step of writing the data and the mapping information corresponding to the data into different clusters of the plurality of clusters is performed by a programming operation on the memory page.

4. The method of claim 1, wherein the data comprises a user data, garbage collection data or wear-leveling data.

5. The method of claim 1, wherein the mapping information comprises information related to mapping from a logical address of the data to a physical address of the non-volatile memory.

6. The method of claim 1, wherein the mapping information comprises information related to mapping from a physical address of the data to a logical address.

7. The method of claim 1, further comprising:
combining memory pages in different memory blocks to generate a super page.

8. The method of claim 7, further comprising:
writing the data into different memory pages within the super page, respectively.

9. The method of claim 8, wherein the data comprises a user data.

10. The method of claim 1, wherein the data is stored in at least one cluster among the plurality of clusters in the memory page.

11. A non-volatile storage device, comprising:
a non-volatile memory, comprising a plurality of memory blocks, each comprising a plurality of memory pages; and
a memory controller, coupled to the non-volatile memory, for managing the non-volatile memory by executing the following steps:
partitioning a memory page among the plurality of memory pages into a plurality of clusters; and
writing data and a mapping information corresponding to the data into different clusters of the plurality of clusters.

12. The non-volatile storage device of claim 11, wherein the memory controller further executes the following step to manage the non-volatile memory:
mapping a logic address to a physical address with a unit of a cluster.

13. The non-volatile storage device of claim 11, wherein the data and the mapping information corresponding to the data are written into different clusters of the plurality of clusters by a programming operation on the memory page.

14. The non-volatile storage device of claim 11, wherein the data comprises a user data, garbage collection data or wear-leveling data.

15. The non-volatile storage device of claim 11, wherein the mapping information comprises information related to a logical address of the data mapping to a physical address of the non-volatile memory.

16. The non-volatile storage device of claim 11, wherein the mapping information comprises information related to a physical address of the data mapping to a logical address.

17. The non-volatile storage device of claim 11, wherein the memory controller further executes the following step to manage the non-volatile memory:
combining memory pages in different memory blocks to generate a super page.

18. The non-volatile storage device of claim 17, wherein the memory controller further executes the following step to manage the non-volatile memory:
writing the data indifferent memory pages within the super page, respectively.

19. The non-volatile storage device of claim 18, wherein the data comprises a user data.

20. The non-volatile storage device of claim 11, wherein the data is stored in at least one cluster among the plurality of clusters in the memory page.
